(19) United States
(12) Patent Application Publication
(10) Pub. No.: US 2003/0034717 A1
(43) Pub. Date: Feb. 20, 2003

(54) Computer case with an adjustable space

(76) Inventor: Chun Chieh Yao, Chang Hua Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/928,329

(22) Filed: Aug. 14, 2001

(51) Int. Cl. H05K 7/18

(52) U.S. Cl. 312/223.1; 312/265.1; 312/334.4

(57) ABSTRACT

A computer case comprises plural horizontal beams and plural vertical beams connected to the horizontal beams to thereby define a space and two lateral sides delimiting the space. Plural horizontal mounting members are mounted to each lateral side, each mounting member comprising a horizontal row of engaging holes. Plural vertical mounting members are mounted to the horizontal mounting members that are mounted to a respective lateral side. Each vertical mounting member comprises two mounting sections extending along different planes that are not parallel or coincident to each other. The mounting sections are engaged with the horizontal row of engaging holes of the horizontal mounting members to thereby form a subspace that is adjustable in volume.

### BACKGROUND OF THE INVENTION

1. Field of the Invention

The present invention relates to a computer case with an adjustable space.

2. Description of the Related Art

Computers are a necessity in the modem world. Most parts and peripherals of a computer are mounted inside a computer case to prevent damage. Currently, a computer case can only be used to accommodate a server of a specific size, as the inner space of the computer case is not adjustable. Thus, servers of different sizes cannot be mounted in the same computer case.

### SUMMARY OF THE INVENTION

An object of the present invention is to provide an improved computer case that has an adjustable space for mounting servers of different sizes.

A computer case in accordance with the present invention comprises:

plural horizontal beams and plural vertical beams connected to said plural horizontal beams to thereby define a space and two lateral sides delimiting the space;

plural horizontal mounting members mounted to each said lateral side, each of said plural mounting members comprising a horizontal row of engaging holes; and

plural vertical mounting members mounted to said plural horizontal mounting members that are mounted to a respective said lateral side, each of said plural vertical mounting members comprising at least two mounting sections extending along different planes that are not parallel or coincident to each other, said at least two mounting sections being selected to engage with said horizontal row of engaging holes of said plural horizontal mounting members to thereby form a subspace that is adjustable in volume.

In a preferred embodiment of the present invention, a computer case comprises:

plural horizontal beams and plural vertical beams connected to said plural horizontal beams to thereby define a space and two lateral sides delimiting the space;

plural horizontal mounting members mounted to each said lateral side, each of said

plural mounting members comprising a horizontal row of engaging holes; and plural vertical mounting members mounted to said plural horizontal mounting members that are mounted to a respective said lateral side, each of said plural vertical mounting members comprising a vertical central portion having a first vertical edge and a second vertical edge, a first wing projecting from a first vertical edge of said vertical central portion and extending along a plane orthogonal to said vertical central portion, and a second L-shaped wing comprising a first section projecting from a second vertical edge of said vertical central portion and extending along a plane parallel to said first wing and a second section extending away from said first wing along a plane parallel to said vertical central portion;

said first wing of each of said plural vertical mounting members comprising a first vertical row of engaging holes;

said second L-shaped wing of each of said plural vertical mounting members comprising a second vertical row of engaging holes; and

means for attaching said plural vertical mounting members to said plural horizontal mounting members, wherein optional ones of said horizontal row of engaging holes of said plural horizontal mounting members being aligned with optional ones of said first vertical row and said second vertical row of engaging holes of said plural vertical mounting members to thereby form a subspace that is adjustable in volume.

Other objects, advantages, and novel features of the invention will become more apparent from the following detailed description when taken in conjunction with the accompanying drawings.

### BRIEF DESCRIPTION OF THE DRAWINGS

FIG. 1 is an exploded perspective view of a computer case in accordance with the present invention.

FIG. 2 is an enlarged view of a vertical mounting member and a horizontal mounting member of the computer case in accordance with the present invention.

FIG. 3 is a perspective view of a portion of the vertical mounting member in accordance with the present invention.

FIG. 4 is a perspective view of the computer case in accordance with the present invention, wherein a front sheet and a top sheet of the computer case are removed to show the interior structure.

FIG. 5 is a sectional view taken along line 5-5 in FIG. 4.

FIG. 6 is a sectional view taken along line 6-6 in FIG. 4.

FIG. 7 is a perspective view illustrating another arrangement of the vertical mounting members.

### DETAILED DESCRIPTION OF THE PREFERRED EMBODIMENTS

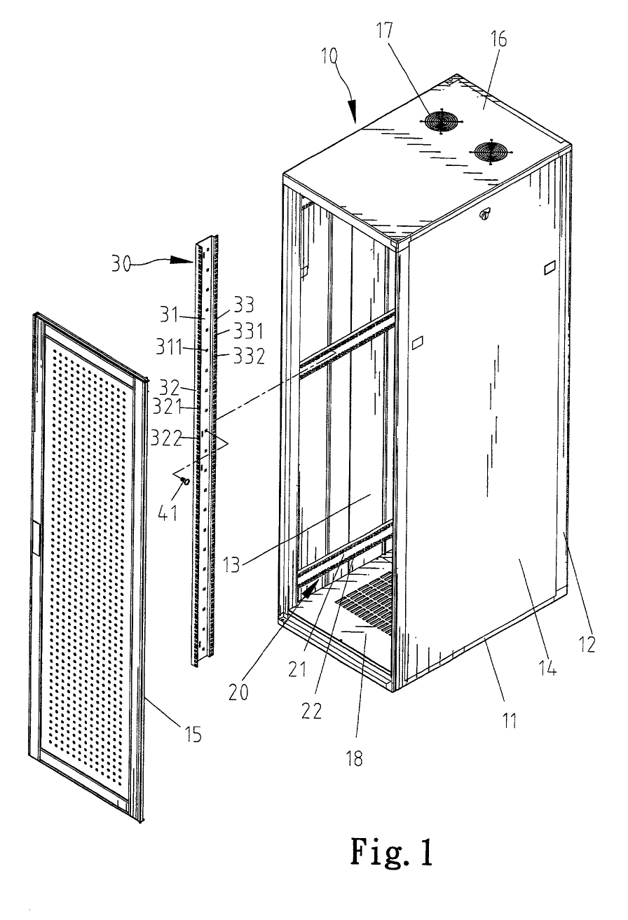

A Referring to FIG. 1, a first embodiment of a computer case 10 in accordance with the present invention generally comprises plural vertical beams 12, plural horizontal beams 11, two side sheets 14, front and rear sheets 15, and top and bottom sheets 16 and 18, thereby defining a space 13. Heat-dissipating fans 17 are mounted on the top sheet 16 for dissipating heat in the space 13 during operation of computer elements (not shown) mounted in the computer case 10.

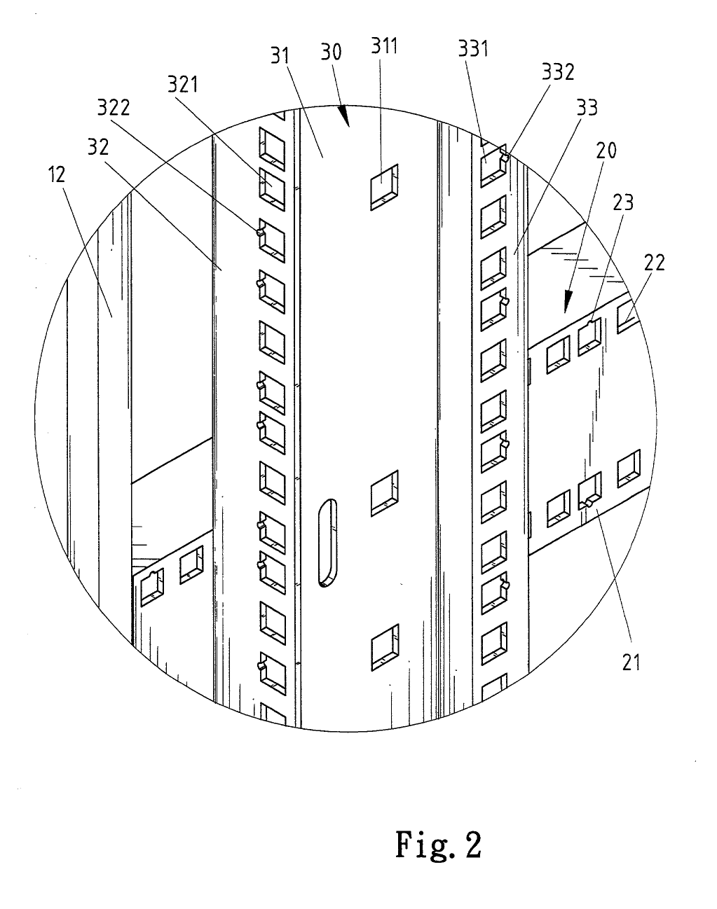

The computer case 10 further comprises plural horizontal mounting members 20 securely attached to an inner side of each side sheet 14. In this embodiment, three horizontal mounting members 20 are mounted to an upper portion, an intermediate portion, and a lower portion of the inner side of each side sheet 14, respectively. Each horizontal mounting member 20 comprises an upper horizontal row of engaging holes 22 on an upper portion thereof and a lower horizontal row of engaging holes 21 on a lower portion thereof. As illustrated in FIG. 2, plural marks 23 are formed on each of the upper portion and the lower portion of each horizontal mounting member 20 at regular intervals. Preferably, each mark is a notch 23 defined in a wall defining a corresponding hole 21, 22, and the notches 23 on the upper portion of a respective horizontal mounting member 20 are aligned with those of the lower portion of the respective horizontal mounting member 20.

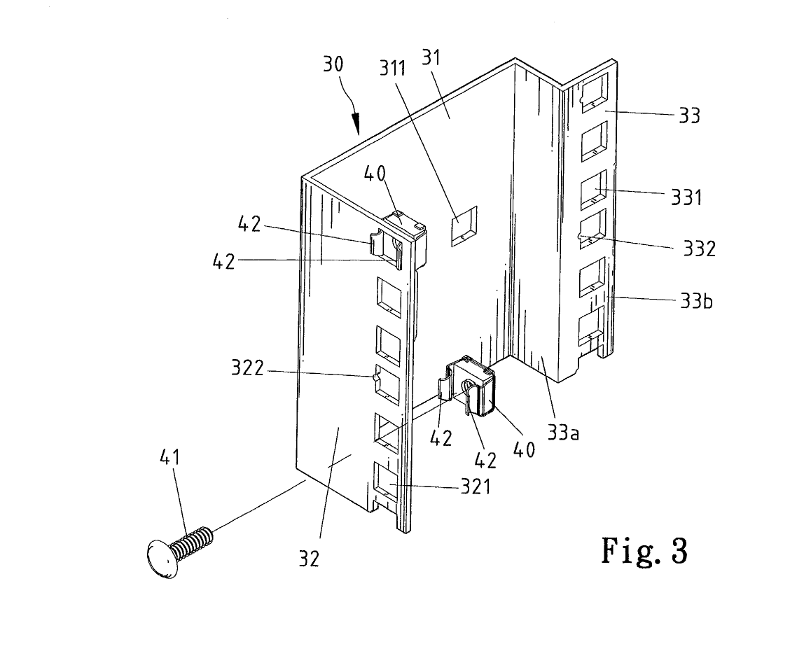

The computer case 10 further comprises plural vertical mounting members 30 mounted to the horizontal mounting members 20 on the inner side of each side sheet 14. Each vertical mounting member 30 comprises a vertical central portion 31 having a vertical row of engaging holes 311. Each of plural bolts 41 is extended through one of the engaging holes 311 of the vertical mounting member 30 and engaged with a nut 40 securely engaged in a corresponding one of the engaging holes 21, 22 of the corresponding horizontal mounting member 30. An embodiment of the nut 40 used in this invention can be a square nut 40 (FIG. 3) having two resilient legs 42 so as to be releasably engaged with one of the engaging holes 21, 22.

As illustrated in FIG. 3, each vertical mounting member 30 comprises a wing 32 projecting from a first vertical edge thereof and extending along a plane orthogonal to the vertical central portion 31. The wing 32 comprises a vertical row of engaging holes 321. Plural marks 322 are formed on the wing 32 at regular intervals. Preferably, each mark is a notch 322 defined in a wall defining a corresponding hole 321. Each vertical mounting member 30 further comprises an L-shaped wing 33 projecting from a second vertical edge thereof and extending firstly along a plane parallel to the wing 32 and then extending outwardly away from the wing 32 along a plane parallel to the vertical central portion 31. Namely, the L-shaped wing 33 comprises a first section 33a extending along a plane parallel to the wing 32 and a second section 33b extending away from the wing 32 along a plane parallel to the vertical central portion 31. The second section 33b of the L-shaped wing 33 comprises a vertical row of engaging holes 331. Plural marks 332 are formed on the second section 33b at regular intervals. Preferably, each mark is a notch 332 defined in a wall defining a corresponding hole 331.

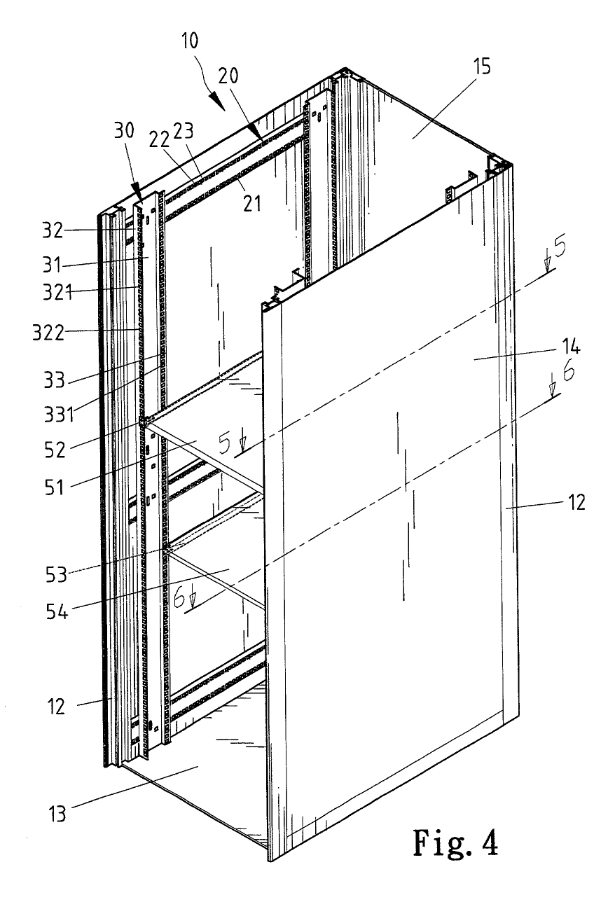

In use, referring to FIG. 4, each vertical mounting member 30 can be mounted to the horizontal mounting members 20 by bolts 41 and nuts 40, as mentioned above. The notches 23 on the horizontal mounting members 20 provide a reference to mount the vertical mounting member 30 vertically.

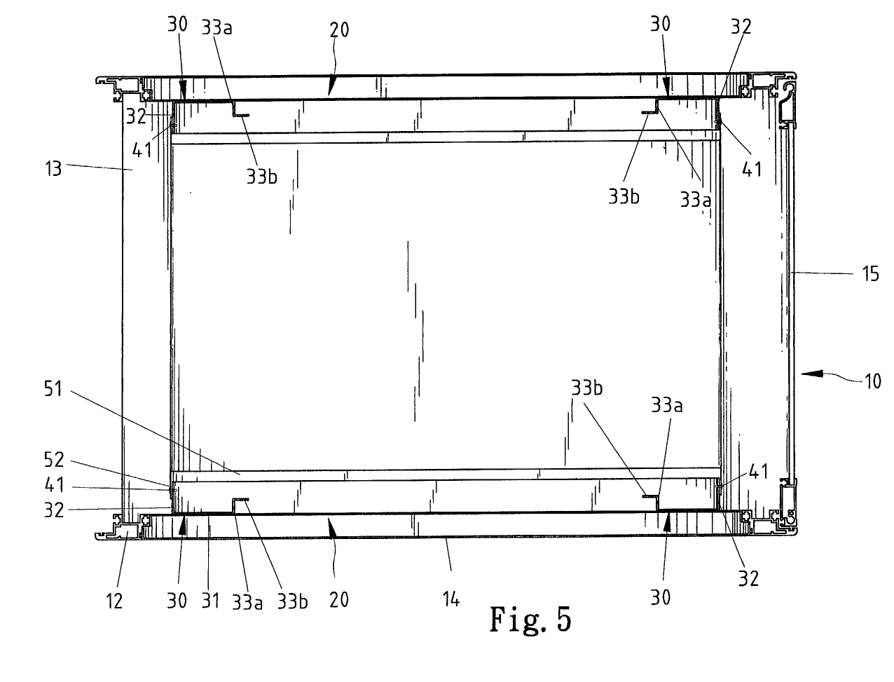

Referring to FIGS. 4 and 5, two lateral sides 52 of a supporting board 51 are attached to the wings 32 of the vertical mounting members 30. Bolts 41 are extended through nuts 40 that are securely positioned in the corresponding engaging holes 322 of the wings 32. The notches 322 on the wings 32 of the vertical mounting members 30 provide a reference to mount the supporting board 51 horizontally. Thus, the supporting board 51 may support a server of an appropriate size.

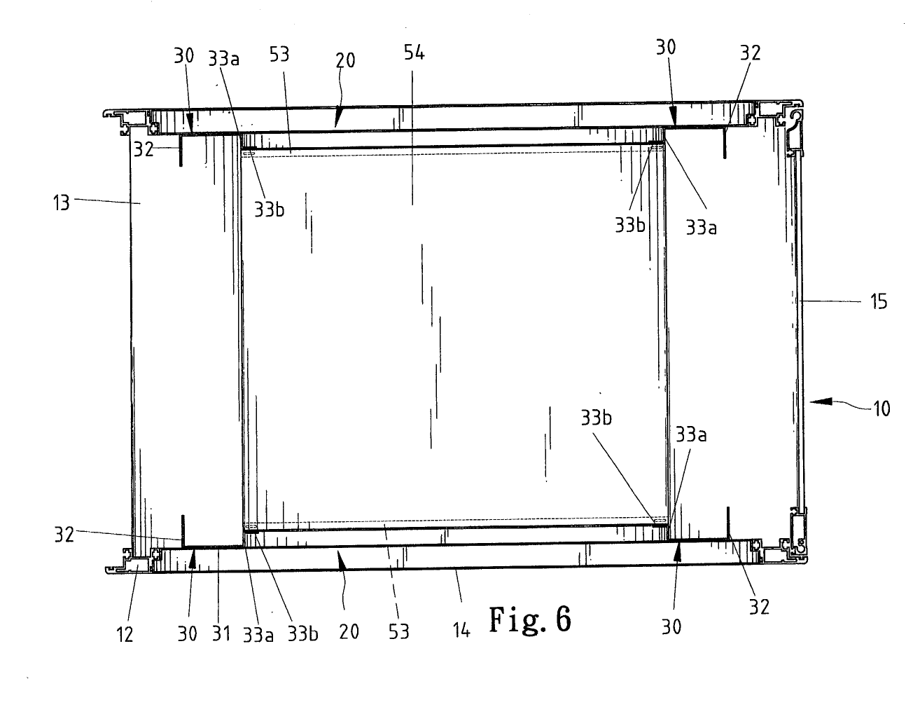

Referring to FIGS. 4 and 6, when supporting a smaller server, two L-shaped brackets 53 are attached to the second sections 33b of the L-shaped wings 33 of the vertical mounting members 30. Bolts 41 are extended through nuts 40 that are securely positioned in the corresponding engaging holes 332 of the L-shaped wings 33. A smaller supporting board 54 is attached to the L-shaped brackets 53. The notches 332 on the L-shaped wings 33 of the vertical mounting members 30 provide a reference to mount the supporting board 54 horizontally. Thus, the supporting board 54 may support a server of a smaller size.

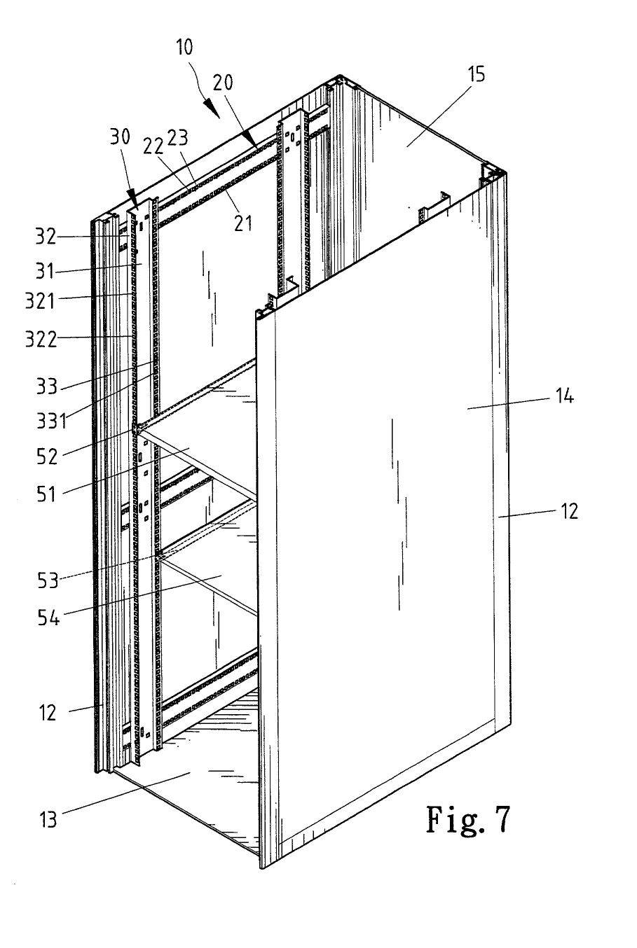

FIG. 7 illustrates another arrangement of the vertical mounting members 30 that are spaced farther when compared with those in the first embodiment shown in FIG. 4. Of course, the distance between the vertical mounting members 30 can be varied according to need.

Each engaging hole 21, 22, 322 and 332 can be screw holes to eliminate the nuts 40. In addition, each horizontal mounting member 20 may have only one row of engaging holes 21 or 22. Furthermore, supporting boards 51 and 54 of various types and sizes can be attached to the vertical mounting members 30 at any desired manner in response to the sizes of the servers, computer elements, or peripherals. The distance between the vertical mounting members 30 can be varied. Of more importance, a subspace that is adjustable in volume is defined by the mounting members 20 and 30 before mounting the supporting boards 51 and 54. The marks (i.e., notches) 23, 322, and 332 provide a reference for mounting. Each vertical mounting member 30 may include more than two mounting sections 32 and 33b to provide optional engagement with the supporting board 51 or brackets 53.

Although the invention has been explained in relation to its preferred embodiment, it is to be understood that many other possible modifications and variations can be made without departing from the scope of the invention as hereinafter claimed.

What is claimed is:

1. A computer case comprising:
plural horizontal beams and plural vertical beams connected to said plural horizontal beams to thereby define a space and two lateral sides delimiting the space;
plural horizontal mounting members mounted to each said lateral side, each of said plural mounting members comprising a horizontal row of engaging holes; and
plural vertical mounting members mounted to said plural horizontal mounting members that are mounted to a respective said lateral side, each of said plural vertical mounting members comprising at least two mounting sections extending along different planes that are not parallel or coincident to each other, said at least two mounting sections being selected to engage with said horizontal row of engaging holes of said plural horizontal mounting members to thereby form a subspace that is adjustable in volume.

2. The computer case as claimed in claim 1, wherein each of said horizontal row of engaging holes is a screw hole.

3. The computer case as claimed in claim 1, further comprising plural marks formed on each of said plural horizontal mounting members at regular intervals.

4. The computer case as claimed in claim 3, wherein said plural marks on one of said plural horizontal mounting members are aligned with said plural marks on the other of said plural horizontal mounting members.

5. The computer case as claimed in claim 3, wherein each of said plural marks is a notch defined in a wall defining a corresponding one of said horizontal row of engaging holes.

6. The computer case as claimed in claim 4, wherein each of said plural marks is a notch defined in a wall defining a corresponding one of said horizontal row of engaging holes.

7. The computer case as claimed in claim 5, wherein each of said plural marks is a notch defined in a wall defining a corresponding one of said horizontal row of engaging holes.

8. The computer case as claimed in claim 1, further comprising plural nuts releasably secured in optional ones of said horizontal row of engaging holes of each of said plural horizontal mounting members, further comprising plural bolts respectively extending through an associated one of said at least two mounting sections of each of said plural vertical mounting members and through said plural nuts.

9. The computer case as claimed in claim 1, wherein each of said at least two mounting sections of each of said plural vertical mounting members comprises a vertical row of engaging holes.

10. A computer case comprising:
plural horizontal beams and plural vertical beams connected to said plural horizontal beams to thereby define a space and two lateral sides delimiting the space;
plural horizontal mounting members mounted to each said lateral side, each of said plural mounting members comprising a horizontal row of engaging holes; and
plural vertical mounting members mounted to said plural horizontal mounting members that are mounted to a respective said lateral side, each of said plural vertical mounting members comprising a vertical central portion having a first vertical edge and a second vertical edge, a first wing projecting from a first vertical edge of said vertical central portion and extending along a plane orthogonal to said vertical central portion, and a second L-shaped wing comprising a first section projecting from a second vertical edge of said vertical central portion and extending along a plane parallel to said first wing and a second section extending away from said first wing along a plane parallel to said vertical central portion;
said first wing of each of said plural vertical mounting members comprising a first vertical row of engaging holes;
said second L-shaped wing of each of said plural vertical mounting members comprising a second vertical row of engaging holes; and
means for attaching said plural vertical mounting members to said plural horizontal mounting members, wherein optional ones of said horizontal row of engaging holes of said plural horizontal mounting members being aligned with optional ones of said first vertical row and said second vertical row of engaging holes of said plural vertical mounting members to thereby form a subspace that is adjustable in volume.

11. The computer case as claimed in claim 10, wherein each of said horizontal row of engaging holes is a screw hole.

12. The computer case as claimed in claim 10, wherein each of said first vertical row of engaging holes is a screw hole.

13. The computer case as claimed in claim 10, wherein each of said second vertical row of engaging holes is a screw hole.

14. The computer case as claimed in claim 10, further comprising plural marks formed on each of said plural horizontal mounting members at regular intervals.

15. The computer case as claimed in claim 14, wherein said plural marks on one of said plural horizontal mounting members are aligned with said plural marks on the other of said plural horizontal mounting members.

16. The computer case as claimed in claim 11, wherein each of said plural marks is a notch defined in a wall defining a corresponding one of said horizontal row of engaging holes.

17. The computer case as claimed in claim 12, wherein each of said plural marks is a notch defined in a wall defining a corresponding one of said first vertical row of engaging holes.

18. The computer case as claimed in claim 13, wherein each of said plural marks is a notch defined in a wall defining a corresponding one of said second vertical row of engaging holes.

19. The computer case as claimed in claim 10, wherein said attaching means comprises plural nuts releasably secured in said optional ones of said horizontal row of engaging holes of each of said plural horizontal mounting members, said attaching means further comprising plural bolts respectively extending through said optional ones of said engaging holes of each of said plural vertical mounting members and through said plural nuts.

20. The computer case as claimed in claim 10, further comprising two side sheets, a front sheet, a rear sheet, a top sheet, and a bottom sheet attached to said plural horizontal beams and said plural vertical beams.
